(19) United States
(12) Patent Application Publication
(10) Pub. No.: US 2024/0387314 A1
(43) Pub. Date: Nov. 21, 2024

(54) SEMICONDUCTOR DEVICE

(71) Applicant: FUJI ELECTRIC CO., LTD., Kawasaki-shi (JP)

(72) Inventor: Katsumi TANIGUCHI, Matsumoto-city (JP)

(73) Assignee: FUJI ELECTRIC CO., LTD., Kawasaki-shi (JP)

(21) Appl. No.: 18/618,862

(22) Filed: Mar. 27, 2024

(30) Foreign Application Priority Data
May 15, 2023 (JP) 2023-079853

(51) Int. Cl. H01L 23/367; H01L 23/495; H01L 23/528; H01L 23/532

(52) U.S. Cl. CPC H01L 23/367; H01L 23/4952; H01L 23/5283; H01L 23/5329

(57) ABSTRACT

A semiconductor device includes a circuit board including: a heat dissipation base having a top surface; an insulating layer having a front surface, and a rear surface which is opposite to the front surface and which is disposed on the top surface of the heat dissipation base, the insulating layer having a placement area set therefor; and a conductive circuit layer having a rear surface which is disposed in the placement area of the insulating layer. A first thickness of the insulating layer in the placement area is less than a second thickness of the insulating layer in an outside area outside the placement area.

### CROSS-REFERENCE TO RELATED APPLICATION

This application is based upon and claims the benefit of priority of the prior Japanese Patent Application No. 2023-079853, filed on May 15, 2023, the entire contents of which are incorporated herein by reference.

### BACKGROUND OF THE INVENTION

### 1. Field of the Invention

The embodiment discussed herein relates to a semiconductor device.

### 2. Background of the Related Art

A semiconductor device includes a base board, a resin layer formed on the base board, and a plurality of conductive circuit layers formed on the resin layer. The semiconductor device also includes semiconductor chips, which are formed on predetermined conductive circuit layers among the plurality of conductive circuit layers (for example, Japanese Laid-open Patent Publication No. 2021-132080).

In addition, another semiconductor device includes a base board, a resin layer formed on the base board, and an external connection terminal having an inner end that is bonded to the resin layer and having an outer end that extends to the outside (for example, International Publication Pamphlet No. WO 2005/094144). In addition, another semiconductor device includes a semiconductor chip that is formed on an inner end of an external connection terminal (for example, Japanese Laid-open Patent Publication No. 2022-037739 and Japanese Laid-open Patent Publication No. 2018-088558).

### SUMMARY OF THE INVENTION

According to one aspect, there is provided a semiconductor device including: a heat dissipation base having a top surface; an insulating layer, having: a front surface, and a rear surface, which is opposite to the front surface and which is disposed on the top surface of the heat dissipation base, the insulating layer having a placement area; and a conductive layer having a rear surface which is in contact with the front surface of the insulating layer in the placement area thereof, wherein a first thickness of the insulating layer in the placement area is less than a second thickness of a part of the insulating layer that is located outside the placement area.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a sectional view of a semiconductor device according to an embodiment;

FIG. 2 is a plan view of the semiconductor device according to the embodiment;

FIG. 3 is a sectional view of a main part of the semiconductor device according to the embodiment;

FIG. 4 is a plan view of the main part of the semiconductor device according to the embodiment;

FIG. 5 is a flowchart illustrating a manufacturing method of the semiconductor device according to the embodiment;

FIG. 6 illustrates a protruding heat dissipation part of a heat dissipation base included in the semiconductor device according to the embodiment;

FIG. 7 is a first sectional view of a main part of a semiconductor device according to the embodiment (modification 1);

FIG. 8 is a second sectional view of a main part) of a semiconductor device according to the embodiment (modification 1);

FIG. 9 is a sectional view of a semiconductor device according to the embodiment (modification 2); and

FIG. 10 is a plan view of the semiconductor device according to the embodiment (modification 2).

### DETAILED DESCRIPTION OF THE INVENTION

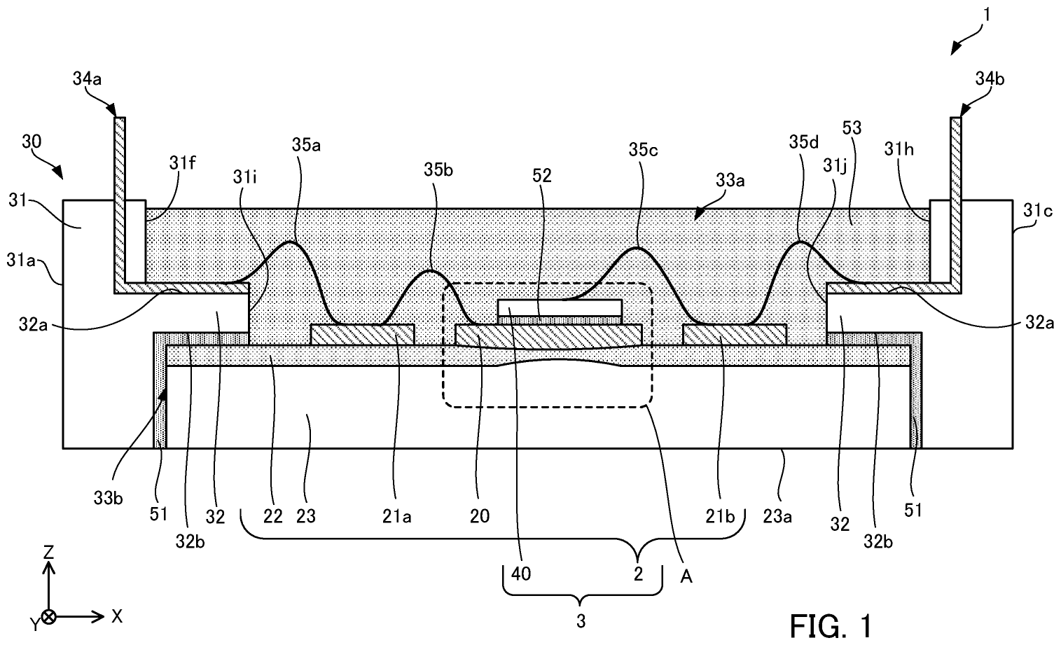

Hereinafter, an embodiment will be described with reference to the accompanying drawings. In the following description, regarding a semiconductor device 1 in FIG. 1, terms “front surface” and “top surface” each express an X-Y surface facing upward (the +Z direction). Likewise, regarding the semiconductor device 1 in FIG. 1, a term “up” expresses the upper direction (the +Z direction). Regarding the semiconductor device 1 in FIG. 1, terms “rear surface” and “bottom surface” each express an X-Y surface facing downward (the −Z direction). Likewise, regarding the semiconductor device 1 in FIG. 1, a term “down” expresses the lower direction (the −Z direction). In all the other drawings, the above terms also mean their respective directions, as needed. The terms “front surface”, “top surface”, “up”, “rear surface”, “bottom surface”, “down”, and “side surface” are simply used as convenient expressions to determine relative positional relationships and do not limit the technical ideas of the embodiment. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, an expression “approximately the same” may be used when an error between two elements is within +10%. In addition, even when two elements are not exactly perpendicular or parallel to each other, two elements may be described as being “perpendicular” or “parallel” to each other if the error is within +10°.

### Embodiment

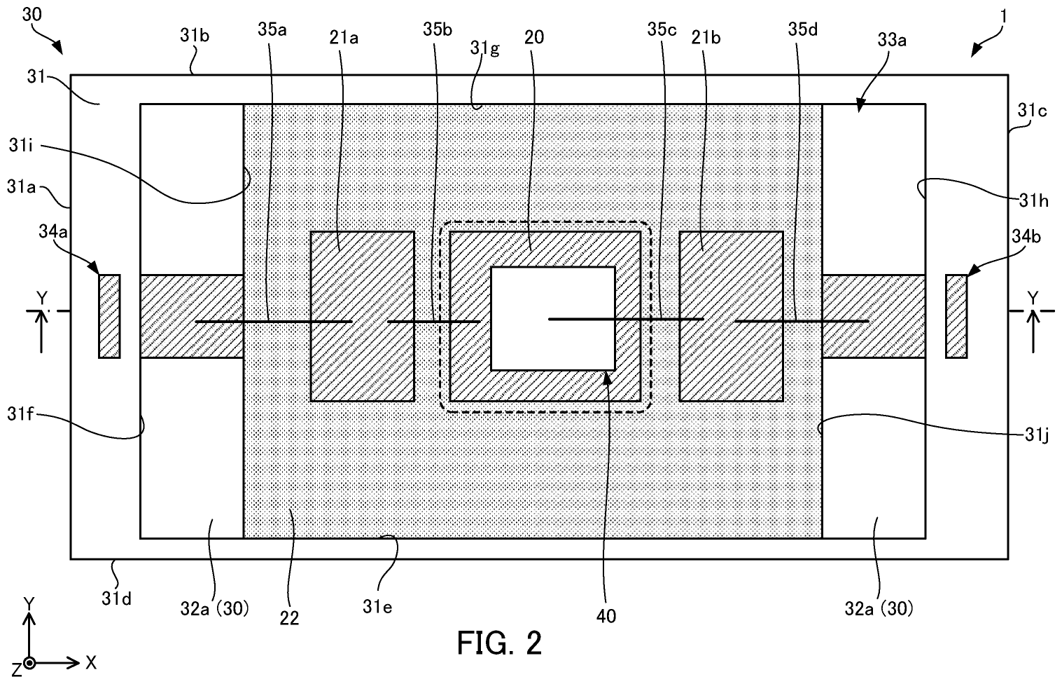

A semiconductor device according to an embodiment will be described with reference to FIGS. 1 and 2. FIG. 1 is a sectional view of a semiconductor device according to an embodiment, and FIG. 2 is a plan view of the semiconductor device according to the embodiment. FIG. 1 is a sectional view taken along a dashed-dotted line Y-Y in FIG. 2. The dashed-dotted line Y-Y is parallel to the longitudinal direction of this semiconductor device 1 and goes through the center of each of a pair of short sides facing each other. FIG. 2 is a plan view of the semiconductor device 1 without a sealing member 53.

The semiconductor device 1 includes a semiconductor unit 3 and a case 30 that stores the semiconductor unit 3. In addition, the semiconductor device 1 includes the sealing member 53 that seals the front surface of the semiconductor unit 3 stored in the case 30.

The semiconductor unit 3 includes a circuit board 2 and a semiconductor chip 40 formed on the circuit board 2. The circuit board 2 includes conductive circuit layers 20, 21a, and 21b, an insulating layer 22, and a heat dissipation base 23.

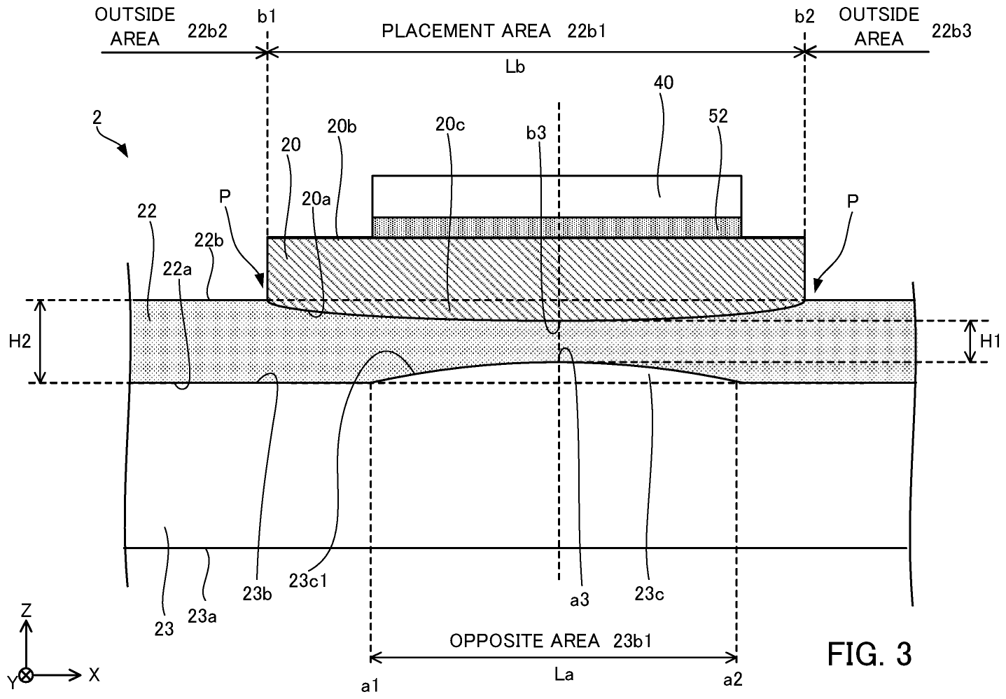

The conductive circuit layers 20, 21a, and 21b are formed on a front surface 22b (see FIG. 3) of the insulating layer 22. These conductive circuit layers 20, 21a, and 21b are made of a metal material having an excellent electrical conductivity. The metal material may be, for example, copper, aluminum, or an alloy containing at least one of these kinds of elements. The conductive circuit layers 20, 21a, and 21b may be formed by, for example, etching a conductive layer formed on the front surface 22b of the insulating layer 22. Alternatively, the conductive circuit layers 20, 21a, and 21b, each of which has previously been formed from a conductive layer, may be attached to the front surface 22b of the insulating layer 22. The semiconductor chip 40 is bonded to the conductive circuit layer 20 via a bonding member 52. The conductive circuit layers 20, 21a, and 21b constitute part of a predetermined circuit. The conductive circuit layers 20, 21a, and 21b illustrated in FIGS. 1 and 2 are only examples. The number, shape, and location of conductive circuit layers may be suitably selected depending on a desired function. Although the thickness of the conductive circuit layers 20, 21a, and 21b depends on the current capacity of the semiconductor device 1, it is preferable that the thickness be 0.1 mm or more, preferably 0.5 mm or more, for example.

For example, solder or sintered metal may be used as the bonding member 52. Lead-free solder is used as the solder. The main component of the lead-free solder is, for example, an alloy containing at least two of tin, silver, copper, zinc, antimony, indium, and bismuth. The solder may contain additive, which is, for example, nickel, germanium, cobalt, or silicon. Since solder containing such additive has improved wettability, luster, and bonding strength, the reliability is improved. The sintered material used for the sintered metal is, for example, powder of silver, iron, copper, aluminum, titanium, nickel, tungsten, molybdenum, or an alloy containing any one of these elements.

The conductive circuit layers 20, 21a, and 21b are formed on predetermined areas of the front surface 22b of the insulating layer 22. The insulating layer 22 may be formed, for example, in the shape of a sheet, and may be made of a resin having a lower thermal resistance and a high insulating property. Examples of the resin include a thermosetting resin and a thermoplastic resin. These resins may contain thermally conductive filler. Such resin containing thermally conductive filler further reduces the thermal resistance of the insulating layer 22 and consequently reduces the difference in thermal expansion coefficient from the heat dissipation base 23. For example, at least one kind of epoxy resin, thermosetting polyimide resin, unsaturated polyester resin, phenol resin, melamine resin, silicone resin, cyanate resin, maleimide resin, and benzoxazine resin is used as the thermosetting resin. For example, at least one kind of polyamide resin, thermoplastic polyimide resin, polyphenylene sulfide resin, and acrylic resin is used as the thermoplastic resin. For example, at least one kind of an oxide material and a nitride material may be used as the thermally conductive filler. Examples of the oxide material include silicon oxide and aluminum oxide. Examples of the nitride material include silicon nitride, aluminum nitride, and boron nitride. The nitride material may be hexagonal boron nitride.

The thickness of the insulating layer 22 depends on the rated voltage of the semiconductor device 1. That is, if the rated voltage of the semiconductor device 1 is high, it is desirable that the thickness of the insulating layer 22 be increased to increase the insulating property thereof. Meanwhile, it is also desirable that the insulating layer 22 be formed as thin as possible to reduce the thermal resistance thereof. The thickness of the insulating layer 22 that achieves these demands is, for example, between 0.05 mm and 0.5 mm, inclusive. The thickness is preferably between 0.12 mm and 0.2 mm, inclusive, more preferably, 0.15 mm or less.

The heat dissipation base 23 has a bottom surface 23a and a top surface 23b, and the insulating layer 22 is formed on the entire top surface 23b. The heat dissipation base 23 is made of a metal material having an excellent thermal conductivity. The metal material is, for example, aluminum, iron, silver, copper, or an alloy containing at least one of these kinds of elements. An example of the alloy is a metal composite, such as aluminum-silicon carbide (Al—SiC) and magnesium-silicon carbide (Mg—SiC). The thickness of the heat dissipation base 23 is between 1 mm and 10 mm, inclusive.

The circuit board 2 will be described in detail below. A cooling unit (not illustrated) may be attached to the rear surface of the case 30 storing the circuit board 2 via a bonding member. In this way, the heat dissipation of the semiconductor device 1 is improved. The bonding member used for attaching the cooling unit to the rear surface of the case 30 is, for example, a brazing material or a thermal interface material. The main component of the brazing material is, for example, at least one of aluminum alloy, titanium alloy, magnesium alloy, zirconium alloy, and silicon alloy. The thermal interface material is an adhesive. Examples of the adhesive include, an elastomer sheet, room-temperature vulcanization (RTV) rubber, gel, and a phase-change material. In addition, the cooling unit is made of, for example, a metal material having an excellent thermal conductivity. The metal material is aluminum, iron, silver, copper, or an alloy containing at least one of these kinds of elements. For example, the cooling unit is a heat sink including at least one fin or is a water-cooled cooling device.

The semiconductor chip 40 includes a power device element made of silicon. The power device element is, for example, a reverse-conducting (RC)-insulated gate bipolar transistor (IGBT). The RC-IGBT has the function of an IGBT, which is a switching element, and the function of a freewheeling diode (FWD), which is a diode element. The semiconductor chip 40 includes a control electrode (a gate electrode) and an output electrode (an emitter electrode), which is a main electrode, on its front surface. The semiconductor chip 40 includes an input electrode (a collector electrode), which is a main electrode, on its rear surface. The control electrode may be formed along one side (or at a center portion on one side) of the front surface of the semiconductor chip 40, for example. The output electrode may be formed at a center portion of the front surface of the semiconductor chip 40. The input electrode may be formed at an area including a center portion of the rear surface of the semiconductor chip 40.

Instead of an RC-IGBT, a semiconductor chip including a switching element and a semiconductor chip including a diode element may be used for the semiconductor chip 40. This switching element is, for example, an IGBT or a power metal-oxide-semiconductor field-effect transistor (MOSFET). The semiconductor chip includes, for example, an input electrode (a drain electrode or a collector electrode) as a main electrode on its rear surface, and includes a control electrode (a gate electrode) and an output electrode (a source electrode or an emitter electrode), which is a main electrode, on its front surface. Examples of the diode element include a Schottky barrier diode (SBD) and a P-intrinsic-N (PiN) diode, which are used as an FWD. This semiconductor chip includes an output electrode (a cathode electrode) as a main electrode on its rear surface, and includes an input electrode (an anode electrode) as a main electrode on its front surface.

The semiconductor chip 40 may include a power MOSFET as a switching element. In this semiconductor chip 40, the body diode of the power MOSFET may function in the same way as an FWD of an RC-IGBT. This semiconductor chip 40 includes a control electrode (a gate electrode) and an output electrode (a source electrode), which is a main electrode, on its front surface. The semiconductor chip includes an input electrode (a drain electrode), which is a main electrode, on its rear surface. The semiconductor chip 40 may preferably be made of silicon carbide.

The rear surface of the semiconductor chip 40 is bonded to the predetermined conductive circuit layer 20 on the insulating layer 22 via the bonding member 52. The conductive circuit layer 20 may be connected to the conductive circuit layer 21a via a wire 35b. The output electrode on the front surface of the semiconductor chip 40 may be connected to the conductive circuit layer 21b via a wire 35c.

The wires 35b and 35c (and wires 35a and 35d, which will be described below) are made of a metal material having an excellent electrical conductivity. The metal material may be, for example, gold, silver, copper, aluminum, or an alloy containing at least one of these kinds of elements.

Although FIGS. 1 and 2 illustrate an example in which one semiconductor chip 40 is disposed on the circuit board 2, the embodiment is not limited to this example. A plurality of semiconductor chips 40 may be disposed as needed, depending on the design. In addition, instead of the wires 35b and 35c (and the wires 35a and 35d, which will be described below), a lead frame or a ribbon may be used.

The case 30 includes a frame part 31 and external connection terminals 34a and 34b, which are integrally formed inside the frame part 31. The case 30 is formed by injection molding using thermoplastic resin such that the frame part 31 integrally includes the external connection terminals 34a and 34b. Examples of the thermoplastic resin used herein include polyphenylene sulfide resin, polybutylene terephthalate resin, polybutylene succinate resin, polyamide resin, and acrylonitrile butadiene styrene resin.

The frame part 31 has a rectangular shape in plan view, and has side walls 31a to 31d constituting four sides of the frame part 31. The side walls 31a and 31c correspond to the short sides of the frame part 31 and are parallel to the lateral direction, and the side walls 31b and 31d correspond to the long sides of the frame part 31 and are parallel to the longitudinal direction.

The frame part 31 has an upper opening part 33a at its top surface. The frame part 31 has inner walls 31e to 31h extending in the +Z direction on the inner side of the side walls 31a to 31d. The upper opening part 33a is sequentially surrounded by the inner walls 31e to 31h in four directions.

In addition, a step part 32 is formed on each of the inner walls 31f and 31h. The step part 32 formed on the inner wall 31f has a front surface 32a, a rear surface 32b, and an innermost wall 31i. The front surface 32a is parallel to the X-Y plane, connects the inner walls 31e and 31g, and protrudes from the inner wall 31f toward the inner wall 31h. The innermost wall 31i is located at a tip of the step part 32, is parallel to the inner wall 31h, and is connected to the front surface 32a. The rear surface 32b is located on the other side of the front surface 32a and is connected to the innermost wall 31i. The step part 32 formed on the inner wall 31h includes a front surface 32a, a rear surface 32b, and an innermost wall 31j. The front surface 32a and the rear surface 32b have already been described above. The innermost wall 31j is located at a tip of the step part 32, is parallel to the inner wall 31h, and is connected to the front surface 32a.

The frame part 31 has a lower opening part 33b at its bottom surface. The lower opening part 33b is connected to the upper opening part 33a via the area surrounded by the innermost walls 31i and 31j of the step parts 32 and the inner walls 31e and 31g.

The external connection terminals 34a and 34b each have an L shape in side view and are each formed integrally with the frame part 31. The inner ends of the external connection terminals 34a and 34b are exposed to the outside on the front surfaces 32a of the step parts 32. The outer ends of the external connection terminals 34a and 34b are parallel to the side walls 31a and 31c and extend vertically upward from the front surface of the frame part 31. These external connection terminals 34a and 34b are made of a metal material having an excellent electrical conductivity. The metal material may be, for example, copper, aluminum, or an alloy containing at least one of these kinds of elements.

The circuit board 2 is attached to the lower opening part 33b of the case 30 (the frame part 31). The circuit board 2 is attached to the lower opening part 33b such that the front surface 22b of the insulating layer 22 is in contact with the rear surfaces 32b of the step parts 32. The circuit board 2 is bonded to the lower opening part 33b by adhesive 51. In the case of the circuit board 2, part of the insulating layer 22, the conductive circuit layers 20, 21a, and 21b, and the semiconductor chip 40 are exposed to the outside in the area surrounded by the innermost walls 31i and 31j of the step parts 32 of the frame part 31 and the inner walls 31e and 31g. The main component of the adhesive 51 is a material having a high heat resistance and a low water absorption. Examples of the material include silicone resin, cyanate resin, phenol resin, and polyimide resin.

In addition, the conductive circuit layer 21a and the external connection terminal 34a are electrically connected to each other via the wire 35a. The conductive circuit layer 21b and the external connection terminal 34b are electrically connected to each other via the wire 35d.

The upper opening part 33a of the case 30 (the frame part 31) is filled with the sealing member 53. In this way, the insulating layer 22, the conductive circuit layers 20, 21a, and 21b, the semiconductor chip 40, and the wires 35a to 35d in the upper opening part 33a are sealed by the sealing member 53. The sealing member 53 contains a thermosetting resin and inorganic filler contained in the thermosetting resin. The main component of the thermosetting resin is, for example, at least one kind selected from a group including epoxy resin, phenol resin, and melamine resin. Preferably, the main component of the thermosetting resin is epoxy resin. An inorganic material of which the main component is silicon oxide is used as the inorganic filler. It is possible to maintain a high flame retardance, without blending, for example, halogen-based, antimony-based, or metal hydroxide flame retardant. The inorganic filler is between 70 vol % and 90 vol %, inclusive, of the overall sealing raw material.

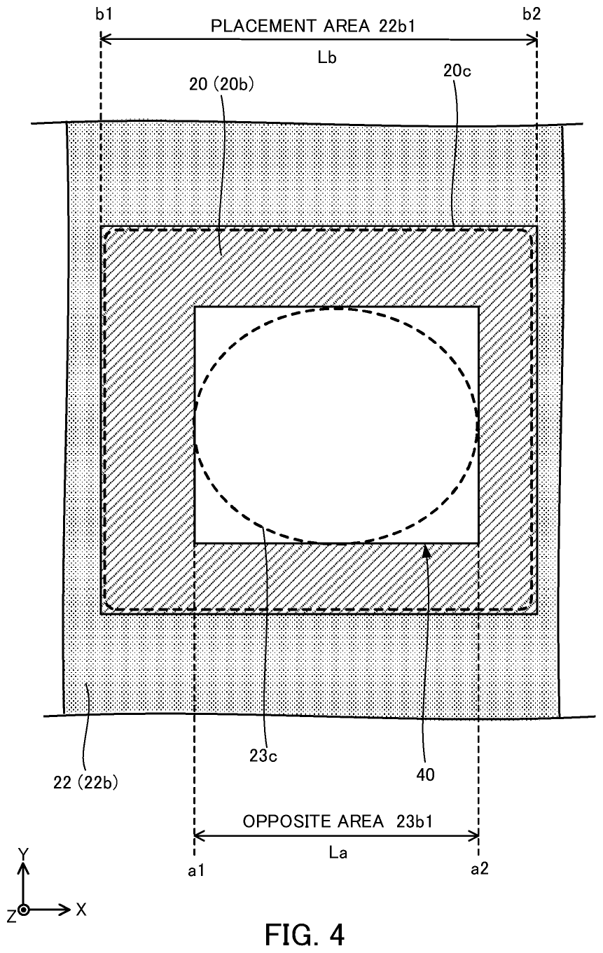

Next, the circuit board 2 will be described in detail with reference to FIGS. 3 and 4. FIG. 3 is a sectional view of a main part of the semiconductor device according to the embodiment, and FIG. 4 is a plan view of the main part of the semiconductor device according to the embodiment. FIG. 3 is an enlarged view of an area A surrounded by a dashed line in FIG. 1. FIG. 4 is an enlarged view of the area A surrounded by the dashed line in FIG. 1 when seen in the −Z direction. In FIGS. 3 and 4, the sealing member 53 is not illustrated.

The area A illustrated in FIGS. 3 and 4 includes the semiconductor chip 40, the conductive circuit layer 20 (a conductive layer) on which the semiconductor chip 40 is disposed, the insulating layer 22, and the heat dissipation base 23. The heat dissipation base 23 has the top surface 23b. The insulating layer 22 has a rear surface 22a (a first rear surface) and the front surface 22b (a first front surface). The rear surface 22a of the insulating layer 22 is disposed on the top surface 23b of the heat dissipation base 23. The conductive circuit layer 20 has a rear surface 20a (a second rear surface) and a front surface 20b (a second front surface). The rear surface 20a of the conductive circuit layer 20 is disposed on the front surface 22b of the insulating layer 22. The semiconductor chip 40 is bonded to the front surface 20b of the conductive circuit layer 20 via the bonding member 52.

In addition, on the front surface 22b of the insulating layer 22, the area where the conductive circuit layer 20 is disposed will be referred to as a placement area 22b1, and the areas outside the placement area 22b1 will be referred to as outside areas 22b2 and 22b3. In addition, the boundary point between the placement area 22b1 of the conductive circuit layer 20 and the outside area 22b2 will be referred to as an end b1 (a second end), and the boundary point between the placement area 22b1 and the outside area 22b3 will be referred to as an end b2 (a second end). That is, a length Lb between the ends b1 and b2 corresponds to the width of the conductive circuit layer 20 in the +X directions. The conductive circuit layer 20 has a rectangular shape in plan view.

The top surface 23b of the heat dissipation base 23 has an area that faces the semiconductor chip 40 via the conductive circuit layer 20, and this area will be referred to as an opposite area 23b1. In addition, two ends of the opposite area 23b1 of the top surface 23b of the heat dissipation base 23 will be referred to as ends a1 and a2 (third ends). That is, a length La between the ends a1 and a2 corresponds to the width of the semiconductor chip 40 in the +X directions. In the case of the circuit board 2, in side view, the ends a1 and a2, which are two ends of the opposite area 23b1 of the heat dissipation base 23 in the +X directions (planar directions), are located inside the ends b1 and b2, which are two ends of the conductive circuit layer 20 in the ±X directions. That is, the length La is shorter than the length Lb.

In the case of the circuit board 2, a first thickness H1 of the insulating layer 22 in the placement area 22b1 is less than a second thickness H2 of the insulating layer 22 in each of the outside areas 22b2 and 22b3 outside the placement area 22b1. That is, since the insulating layer 22 is thinner in the placement area 22b1 in which the semiconductor chip 40 is disposed, the heat from the semiconductor chip 40 transfers easily. In addition, since the insulating layer 22 has the same thickness at the parts corresponding to the outside areas 22b2 and 22b3 outside the placement area 22b1, the insulating layer 22 maintains its insulating property.

In particular, in the present embodiment, a protruding conductive part 20c (an example of a protruding part) is formed in the rear surface 20a of the conductive circuit layer 20, and a protruding heat dissipation part 23c (an example of the protruding part) is formed in the opposite area 23b1 of the top surface 23b of the heat dissipation base 23, the protruding heat dissipation part 23c facing the placement area 22b1. The protruding conductive part 20c and the protruding heat dissipation part 23c convexly protrude toward the insulating layer 22.

The protruding conductive part 20c and the protruding heat dissipation part 23c are formed in a mound, including curved tops b3 and a3 that curve toward the insulating layer 22. In other words, the protruding conductive part 20c and the protruding heat dissipation part 23c have a bowl-like contour having tops b3 and a3 as their tops. In this case, the shortest distance between the tops b3 and a3 in the +Z directions, at which the protruding conductive part 20c and the protruding heat dissipation part 23c are closest to each other, is the first thickness H1.

The first thickness H1 is the shortest distance from the top b3 of the protruding conductive part 20c formed in the rear surface 20a of the conductive circuit layer 20 to the opposite area 23b1 of the heat dissipation base 23, the opposite area 23b1 facing the rear surface 20a. In addition, the first thickness H1 is the shortest distance from the top a3 of the protruding heat dissipation part 23c formed in the opposite area 23b1 of the heat dissipation base 23 to the placement area 22b1 of the conductive circuit layer 20, the placement area 22b1 facing the opposite area 23b1.

FIG. 3 illustrates a case in which the top b3 of the protruding conductive part 20c and the top a3 of the protruding heat dissipation part 23c are located (face each other) on a straight line parallel to the #Z directions. Thus, the distance between the top b3 of the protruding conductive part 20c and the top a3 of the protruding heat dissipation part 23c is the first thickness H1. The first thickness H1 is 0.5 times or more of the second thickness H2, preferably 0.8 times or more of the second thickness H2 and less than the second thickness H2. By setting the first thickness H1 of the insulating layer 22 within this range, the insulating layer 22 maintains its insulating property and has a reduced thermal resistance in the placement area 22b1.

If the first thickness H1 is less than 0.5 times of the second thickness H2, the insulating layer 22 could fail to contain a sufficient amount of filler in the portion having the first thickness H1. To avoid this problem, the overall amount of filler contained in the insulating layer 22 needs to be controlled. If the insulating layer 22 contains a limited amount of filler, the insulating layer 22 has a reduced thermal conductivity. Although the portion of the insulating layer 22, the portion having the first thickness H1, maintains a certain thermal conductivity, the portion having the second thickness H2 has an increased thermal resistance. Thus, the first thickness H1 needs to be 0.5 times or more of the second thickness H2.

If the top b3 of the protruding conductive part 20c and the top a3 of the protruding heat dissipation part 23c do not face each other, the shorter one of the shortest distance from the top b3 of the protruding conductive part 20c to the opposite area 23b1 of the heat dissipation base 23 and the shortest distance from the top a3 of the protruding heat dissipation part 23c to the rear surface 20a of the conductive circuit layer 20 is set as the first thickness H1.

In addition, in plan view, the protruding conductive part 20c may have a rectangular shape that matches the conductive circuit layer 20, for example. In plan view, the protruding heat dissipation part 23c may have a circular shape (or an oval shape) that is inscribed in the contour of the semiconductor chip 40, for example. These shapes in plan view are examples. In plan view, as long as the protruding conductive part 20c has a size that covers the protruding heat dissipation part 23c, the protruding conductive part 20c may have a circular shape (or an oval shape) or the protruding heat dissipation part 23c may have a rectangular shape.

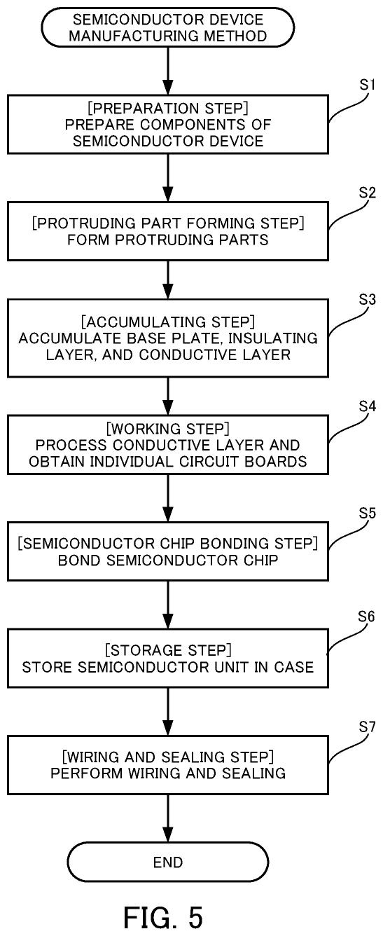

Next, a manufacturing method of the semiconductor device 1 will be described with reference to FIG. 5. FIG. 5 is a flowchart illustrating a manufacturing method of the semiconductor device according to the embodiment. First, a preparation step (step S1) of preparing components of the semiconductor device 1 is performed. The components prepared in this step are, for example, the semiconductor chip 40, the case 30, a conductive layer for the conductive circuit layers 20, 21a, and 21b, the insulating layer 22, a base plate for the heat dissipation base 23, and a raw material for the sealing member 53. Other than these components, needed components are also prepared. Manufacturing apparatuses used for manufacturing the semiconductor device 1 may also be prepared. Examples of the manufacturing apparatuses include a bonding apparatus and a sealing apparatus for the sealing member.

Next, in order to manufacture the circuit board 2, first, a protruding portion forming step (step S2) of forming the protruding conductive part 20c included in the conductive circuit layer 20 and the protruding heat dissipation part 23c included in the heat dissipation base 23 is performed. Convex parts are formed in the conductive layer and the base plate by using a press die. In this step S2, a plurality of convex parts are formed in a plurality of parts of the conductive layer. These parts will be used as the conductive circuit layers 20. In addition, a plurality of convex parts are formed in a plurality of parts of the base plate. These parts will be used as the heat dissipation bases 23.

Next, in order to manufacture the circuit board 2, an accumulating step (step S3) of accumulating the conductive layer in which the protruding conductive parts have been formed in step S2 on the base plate in which the protruding heat dissipation parts have been formed in step S2 via an insulating layer is performed. In this step, the insulating layer is disposed on the base plate, with the surface on which the protruding heat dissipation parts 23c have been formed facing upward. The conductive layer is disposed on the insulating layer, with the surface on which the protruding conductive parts 20c have been formed facing downward. Next, heat is applied to these accumulated components, and pressure is applied to the components in the accumulation direction. As a result, the components are firmly attached to each other. This attachment process is carried out under an inert gas atmosphere or under vacuum.

Next, in order to manufacture the circuit board 2, a working step (step S4) of processing the conductive layer accumulated in step S3 such that the conductive circuit layers 20, 21a, and 21b formed and dividing the conductive layer into individual pieces is performed. The topmost conductive layer accumulated in step S3 is masked by using a photosensitive resist mask based on a predetermined pattern, is etched into the pattern, and the photosensitive resist mask is removed. As a result, a plurality of sets of conductive circuit layers 20, 21a, and 21b are formed. Next, by dividing these sets of conductive circuit layers 20, 21a, and 21b into individual pieces, a plurality of circuit boards 2 are obtained.

Next, a semiconductor chip bonding step (step S5) of bonding a semiconductor chip 40 to the conductive circuit layer 20 of the individual circuit board 2 is performed. For example, as the bonding member 52, solder is applied to the conductive circuit layer 20 of the circuit board 2. Next, heating is performed so as to melt the solder, and the semiconductor chip 40 is disposed on the molten solder. After the molten solder is solidified, the semiconductor chip 40 is bonded to the conductive circuit layer 20 of the circuit board 2 via the solder. Thus, the semiconductor unit 3 in which the semiconductor chip 40 is bonded to the circuit board 2 is obtained.

Next, a storage step (step S6) of storing the semiconductor unit 3 in the case 30 by attaching the semiconductor unit 3 to the lower opening part 33b of the case 30 is performed. The circuit board 2 of the semiconductor unit 3 is attached to the lower opening part 33b of the case 30 (the frame part 31) via the adhesive 51.

Next, a wiring and sealing step (step S7) of wiring the semiconductor unit 3 stored in the case 30 and sealing the semiconductor unit 3 is performed. The inner end of the external connection terminal 34a exposed to the outside in the upper opening part 33a of the case 30 is connected to the conductive circuit layer 21a via the wire 35a, and the conductive circuit layers 21a and 20 are connected to each other via the wire 35b. In addition, the output electrode of the semiconductor chip 40 is connected to the conductive circuit layer 21b via the wire 35d, and the conductive circuit layer 21b and the inner end of the external connection terminal 34b are connected to each other via the wire 35d. The upper opening part 33a of the case 30 is filled with the sealing member 53, so as to seal the upper opening part 33a. Thus, the semiconductor device 1 illustrated in FIGS. 1 and 2 is obtained.

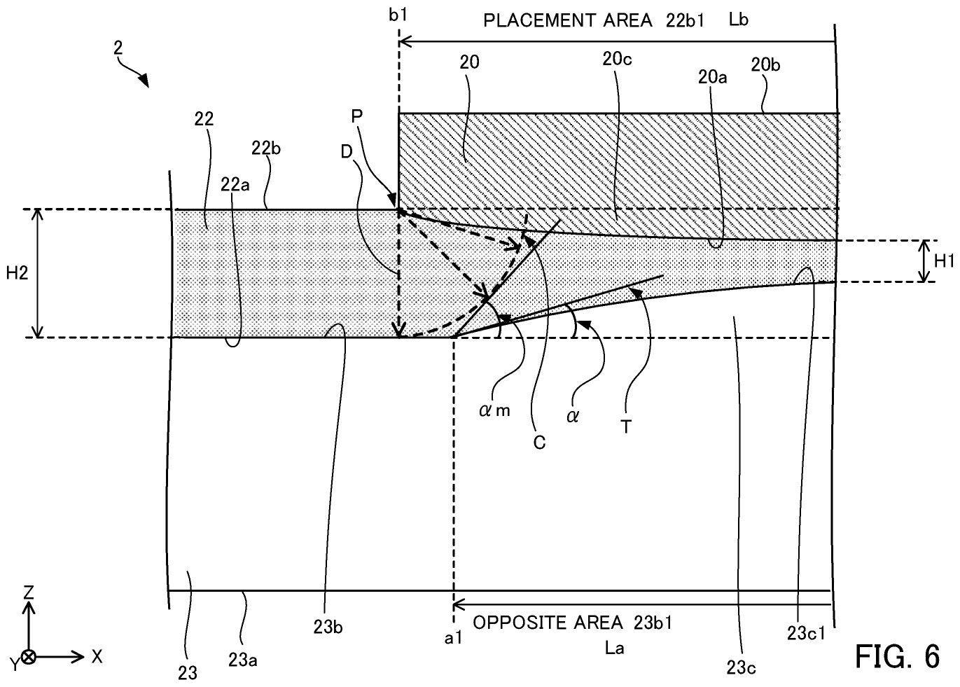

Next, the protruding heat dissipation part 23c formed in the heat dissipation base 23 and the protruding conductive part 20c formed in the conductive circuit layer 20 will be described in detail with reference to FIG. 6. FIG. 6 illustrates the protruding heat dissipation part in the heat dissipation base included in the semiconductor device according to the embodiment. FIG. 6 is an enlarged view of a part near the ends b1 and a1 in FIG. 3.

As described above, the circuit board 2 includes the conductive circuit layer 20 including the protruding conductive part 20c, the insulating layer 22, and the heat dissipation base 23 including the protruding heat dissipation part 23c. The protruding conductive part 20c is formed in a location of the conductive circuit layer 20, the location facing the placement area 22b1. The protruding conductive part 20c is the part where the rear surface 20a protrudes. The protruding heat dissipation part 23c is formed in the opposite area 23b1 of the top surface 23b of the heat dissipation base 23.

In addition, in side view, the ends a1 and a2 of the opposite area 23b1 of the heat dissipation base 23 in the ±X directions (planar directions) are located inside the ends b1 and b2 of the conductive circuit layer 20 in the +X directions. That is, the length Lb is longer than the length La. In FIG. 6, only the ends a1 and b1 are illustrated.

An outer periphery 23c1 of the protruding heat dissipation part 23c rises at a predetermined rising angle α from the end a1 of the opposite area 23b1. The outer periphery 23c1 of the protruding heat dissipation part 23c rises up to the top a3, and after the top a3, slopes downward to the end a2 of the opposite area 23b1 (see FIG. 3). The outer periphery 23c1 of the protruding heat dissipation part 23c connects to the end a2 of the opposite area 23b1 at the rising angle α. A tangent line T is set for the protruding heat dissipation part 23c. This tangent line T extends, from the end a1, in contact with the outer periphery 23c1 of the protruding heat dissipation part 23c. Although not illustrated, another tangent line T is also set for the protruding heat dissipation part 23c, and this tangent line T extends, from the end a2, in contact with the outer periphery 23c1 of the protruding heat dissipation part 23c.

The protruding conductive part 20c falls, at a predetermined angle, from the end b1 of the rear surface 20a of the conductive circuit layer 20. As illustrated in FIG. 3, the protruding conductive part 20c falls downward to the top b3, and after the top b3, slopes upward to the end b2 of the rear surface 20a. The protruding conductive part 20c connects to the end b2 of the rear surface 20a at the predetermined angle. The protruding conductive part 20c and the protruding heat dissipation part 23c have their respective heights such that these parts 20c and 23c do not come in contact with each other.

In particular, the maximum value of the rising angle α of the tangent line T of the protruding heat dissipation part 23c represents the angle at which, in side view, the outer periphery 23c1 of the protruding heat dissipation part 23c is in contact with a circumference part C, which is in the insulating layer 22, of a circle having its center at the end b1 (a triple point P) of the conductive circuit layer 20 and having its radius D equal to the second thickness H2.

For example, an angle αm illustrated in FIG. 6 is the angle at which the outer periphery 23c1 of the protruding heat dissipation part 23c is in contact with the circumference part C. If the rising angle α of the tangent line T is greater than the angle αm, the distance from the end b1 (the triple point P) of the conductive circuit layer 20 to the protruding heat dissipation part 23c is less than the second thickness H2.

The triple point P is the point where the conductive circuit layer 20, the insulating layer 22, and the sealing member 53 (see FIG. 1) converge, and therefore, the electric field is easily concentrated. Thus, the protruding heat dissipation part 23c needs to have a sufficient creepage distance from the triple point P. According to the present embodiment, this creepage distance is the second thickness H2.

If the rising angle α of the tangent line T is greater than the angle αm, because the distance from the end b1 (the triple point P) of the conductive circuit layer 20 to the protruding heat dissipation part 23c is less than the second thickness H2, the creepage distance is not maintained.

Thus, the rising angle α of the tangent line T of the protruding heat dissipation part 23c needs to be in a range in which, in side view, the protruding heat dissipation part 23c is not in contact with the circumference part C, which is in the insulating layer 22, of the circle having its center at the end b1 of the conductive circuit layer 20 and having its radius D equal to the second thickness H2.

The protruding conductive part 20c and the protruding heat dissipation part 23c may be formed in another shape other than a mound shape. As long as the creepage distance from the triple point P, etc., is maintained, the protruding conductive part 20c and the protruding heat dissipation part 23c may have a box shape, for example. If the protruding conductive part 20c and the protruding heat dissipation part 23c have a box shape, the corners of these parts 20c and 23c need to be rounded. The electric field is easily concentrated on a corner, and dielectric breakdown could occur.

Thus, the above-described semiconductor device 1 includes the circuit board 2 including: the heat dissipation base 23 having the top surface 23b; the insulating layer 22 having the front surface 22b on which the placement area 22b1 is set and the rear surface 22a which is opposite to the front surface 22b and which is disposed on the top surface 23b of the heat dissipation base 23; and the conductive circuit layer 20 having the rear surface 20a which is disposed in the placement area 22b1 of the insulating layer 22. The first t thickness H1 of the insulating layer 22 in the placement area 22b1 is less than the second thickness H2 of the insulating layer 22 in the outside areas 22b2 and 22b3 outside the placement area 22b1. Since the insulating layer 22 is thinner in the placement area 22b1 corresponding to the semiconductor chip 40, the heat from the semiconductor chip 40 transfers easily. In addition, since the insulating layer 22 has a certain thickness at the portion corresponding to the outside areas 22b2 and 22b3 outside the placement area 22b1, the insulating property is maintained. The semiconductor device 1 including the above-described circuit board 2 maintains its insulating property and has an improved heat dissipation. Therefore, deterioration in reliability is prevented.

The present embodiment has been described by using, as an example, the semiconductor device 1 in which the semiconductor chip 40 is disposed on the conductive circuit layer 20 of the above-described circuit board 2. A different heat-generating circuit component other than the semiconductor chip 40 may be disposed on the conductive circuit layer 20 of the circuit board 2. Examples of the circuit component include a wiring member and an electronic component. The wiring member is, for example, an external connection terminal, a lead frame, or a contact component. The electronic component is, for example, a capacitor or a control integrated circuit (IC).

### (Modification 1)

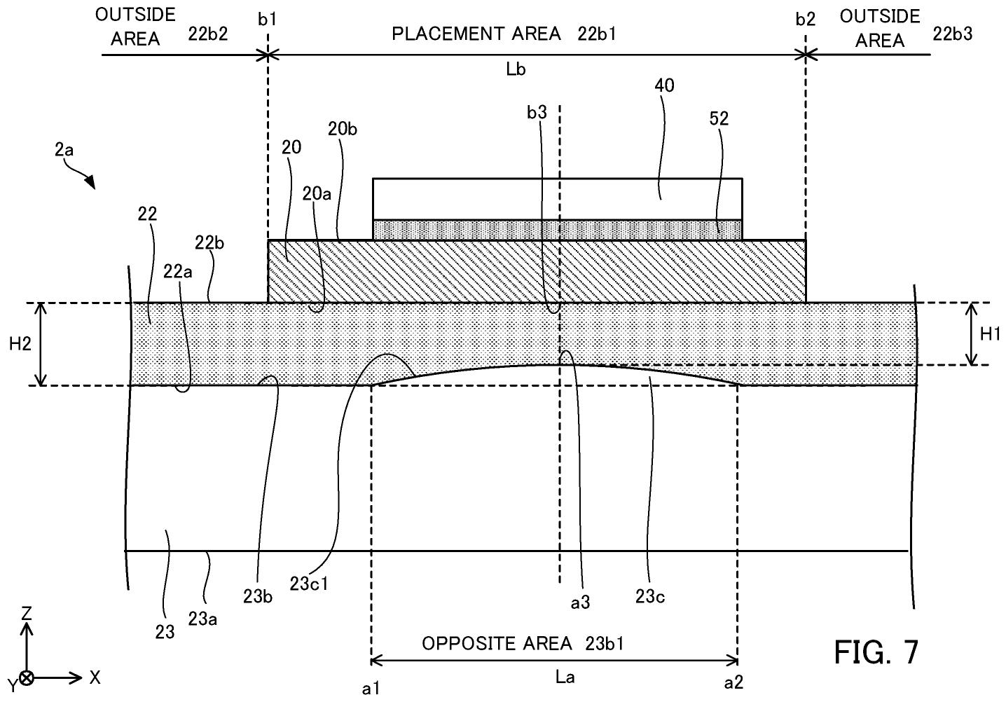

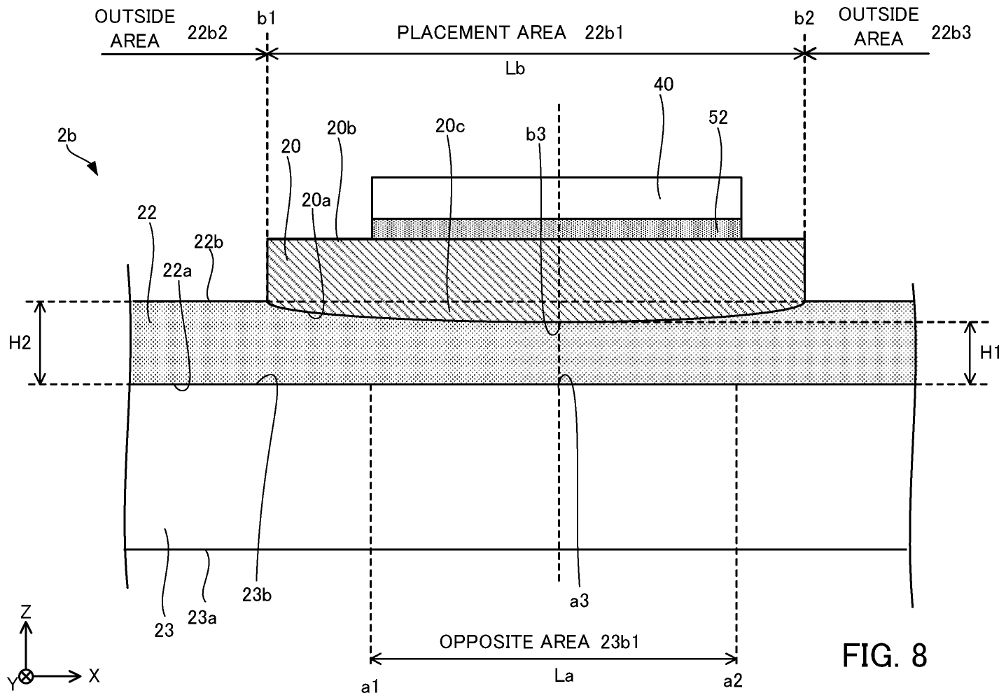

Hereinafter, various modifications of the circuit board 2 will be described. First, two kinds of circuit boards according to modification 1 will be described with reference to FIGS. 7 and 8. FIG. 7 is a first sectional view of a main part of a semiconductor device according to the embodiment (modification 1). FIG. 8 is a second sectional view of a main part of a semiconductor device according to the embodiment (modification 1). FIGS. 7 and 8 correspond to the sectional view of the semiconductor device 1 in FIG. 3. FIG. 7 illustrates a circuit board 2a, and FIG. 8 illustrates a circuit board 2b.

In the case of the circuit board 2 illustrated in FIG. 3, the protruding conductive part 20c is formed in the conductive circuit layer 20, and the protruding heat dissipation part 23c is formed in the heat dissipation base 23. However, in the circuit board 2a according to modification 1, the protruding heat dissipation part 23c is formed in the heat dissipation base 23. In the circuit board 2b according to modification 1, the protruding conductive part 20c is formed in the conductive circuit layer 20.

With these circuit boards 2a and 2b, too, the first thickness H1 of the insulating layer 22 in the placement area 22b1 is less than the second thickness H2 of the insulating layer 22 in the outside areas 22b2 and 22b3 outside the placement area 22b1. The insulating layer 22 transfers the heat from the semiconductor chip 40 more easily than a case without the protruding conductive part 20c and the protruding heat dissipation part 23c. In addition, since the insulating layer 22 has a certain thickness at the portion corresponding to the outside areas 22b2 and 22b3 outside the placement area 22b1, the insulating property is maintained. The semiconductor device 1 including the circuit board 2a or 2b maintains its insulating property and has an improved heat dissipation. Therefore, deterioration in reliability is prevented.

### (Modification 2)

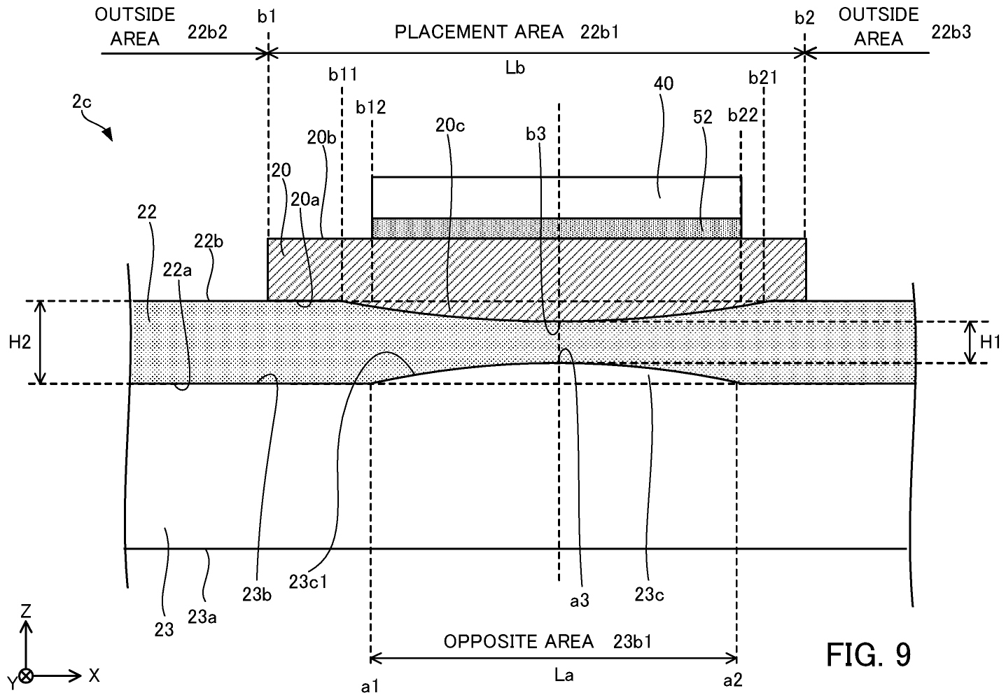

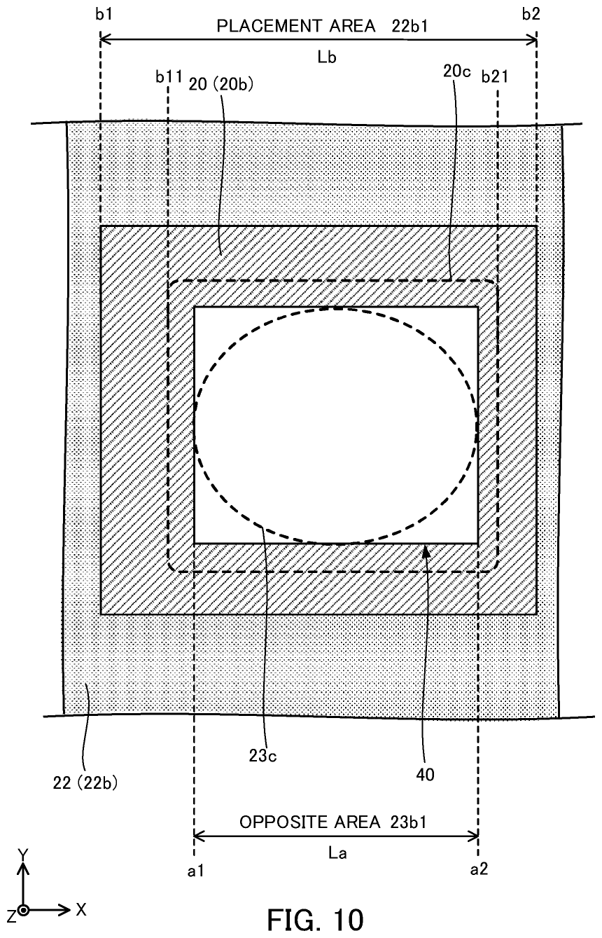

According to modification 2, the protruding conductive part 20c of the conductive circuit layer 20 is formed on the inner side of the rear surface 20a of the conductive circuit layer 20 in the +X directions. A circuit board 2c constructed in this way will be described with reference to FIGS. 9 and 10. FIG. 9 is a sectional view of a semiconductor device according to the embodiment (modification 2). FIG. 10 is a plan view of the semiconductor device according to the embodiment (modification 2). FIG. 9 corresponds to the sectional view of the semiconductor device 1 in FIG. 3, and FIG. 10 corresponds to the plan view of the semiconductor device 1 in FIG. 4.

The circuit board 2c includes a conductive circuit layer 20, an insulating layer 22, and a heat dissipation base 23. The insulating layer 22 and the heat dissipation base 23 are equivalent to those according to the embodiment. A protruding conductive part 20c is formed in the rear surface 20a of the conductive circuit layer 20. Ends b11 and b21 of the protruding conductive part 20c are located inside ends b1 and b2 of the conductive circuit layer 20 (in the #X directions) and are located outside ends b12 and b22 of a semiconductor chip 40 (in the +X directions).

If the ends b11 and b21 of the protruding conductive part 20c are located inside the ends b12 and b22 of the semiconductor chip 40 (in the +X directions), in plan view, the width between the ends b11 and b21 of the protruding conductive part 20c is less than the width between the ends b12 and b22 of the semiconductor chip 40. As a result, the heat dissipation of the semiconductor chip 40 is deteriorated. Thus, it is desirable that the ends b11 and b21 of the protruding conductive part 20c be located outside the ends b12 and b22 of the semiconductor chip 40 (in the +X directions).

In the case of the circuit board 2c, too, the first thickness H1 of the insulating layer 22 in the placement area 22b1 is less than the second thickness H2 of the insulating layer 22 in the outside area 22b2 and 22b3 outside the placement area 22b1. The insulating layer 22 transfers the heat from the semiconductor chip 40 easily. In addition, since the insulating layer 22 has a certain thickness at the portion corresponding to the outside areas 22b2 and 22b3 outside the placement area 22b1, the insulating property is maintained. The semiconductor device 1 including the circuit board 2c maintains its insulating property and has an improved heat dissipation. Therefore, deterioration in reliability is prevented.

The disclosed technique prevents the reliability of a semiconductor device from deteriorating while maintaining the insulating property and improving the heat dissipation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a heat dissipation base having a top surface;
an insulating layer, having:
a front surface, and
a rear surface, which is opposite to the front surface and which is disposed on the top surface of the heat dissipation base, the insulating layer having a placement area; and
a conductive layer having a rear surface which is in contact with the front surface of the insulating layer in the placement area thereof,
wherein a first thickness of the insulating layer in the placement area is less than a second thickness of a part of the insulating layer that is located outside the placement area.

2. The semiconductor device according to claim 1, wherein
the heat dissipation base has, on the top surface thereof, an opposite area facing the placement area of the insulating layer, and
at least one of the rear surface of the conductive layer or the opposite area of the heat dissipation base includes a protruding part convexly protruding toward the insulating layer.

3. The semiconductor device according to claim 2, wherein
each of the opposite area of the heat dissipation base and the conductive layer has two ends in planar directions, and
in a side view of the semiconductor device, the two ends of the opposite area of the heat dissipation base are located inside the two ends of the conductive layer in planar directions.

4. The semiconductor device according to claim 3, wherein the protruding part is formed in a mound shape having a curved top that curves toward the insulating layer.

5. The semiconductor device according to claim 4,
wherein the protruding part is included at least in the opposite area of the heat dissipation base, and
wherein an outer periphery of the protruding part included in the opposite area is connected to the two ends of the opposite area in the planar directions, and rises at a rising angle with respect to the top surface of the heat dissipation base.

6. The semiconductor device according to claim 5, wherein in the side view,
the rising angle is formed between a tangent line, which is tangent to the outer periphery of the protruding part and passes through one of the two ends of the opposite area in the planar directions, and the top surface of the heat dissipation base, and
the rising angle is so set that the tangent line touches a circle having a center thereof at one of the two ends of the conductive layer in the planar directions and having a radius equal to the second thickness.

7. The semiconductor device according to claim 4, wherein the first thickness is a shortest distance between the front surface and the rear surface of the insulating layer in a thickness direction thereof.

8. The semiconductor device according to claim 7, wherein the first thickness is 0.5 times or more of the second thickness and less than the second thickness.

9. The semiconductor device according to claim 8, wherein the first thickness is 0.8 times or more of the second thickness.

10. The semiconductor device according to claim 9, wherein the second thickness is between 0.12 mm and 0.2 mm, inclusive.

11. The semiconductor device according to claim 10, wherein the second thickness is 0.15 mm or less.

12. The semiconductor device according to claim 1, wherein
the conductive layer further has a front surface opposite to the rear surface thereof, and
the semiconductor device further includes a circuit part disposed on the front surface of the conductive layer.

13. The semiconductor device according to claim 12, wherein the circuit part is a semiconductor chip or a connection terminal.

14. The semiconductor device according to claim 1, wherein the insulating layer contains resin as a main component thereof.

15. The semiconductor device according to claim 14, wherein the insulating layer contains a filler.
